(19) United States
(12) Patent Application Publication
(10) Pub. No.: US 2003/0220759 A1
(43) Pub. Date: Nov. 27, 2003

(54) Fail analyzer

(76) Inventor: Takeshi Katayama, Tokyo (JP)

Correspondence Address: DELLETT AND WALTERS, 310 S.W. FOURTH AVENUE, SUITE 1101, PORTLAND, OR, 97204, US

(21) Appl. No.: 10/297,699

(22) PCT Filed: Jun. 11, 2001
(86) PCT No.: PCT/JP01/04894

(30) Foreign Application Priority Data
Jun. 13, 2000 (JP) 2000-176469

(51) Int. Cl. G06F 19/00; G01R 27/28; G01R 31/00; G01R 31/14

(52) U.S. Cl. 702/120

(57) ABSTRACT

It is an object of the invention to provide a fail analyzer that can reduce the time and effort required for printing or editing of fail analysis result.

A printing item setting section 22 sets the various detailed items, including the resolution of the printer 60 and the like, required for printing. A print data generation section 20 generates print data including a general purpose data format while taking account of the resolution. The print data is sent to the printer 60 and then printed on specified sheet. Alternatively, the print data is output as a file and then stored in an analysis result data storing section 40.

### TECHNICAL FIELD

The present invention relates to a fail analyzer that prints the results of measurements of a fail distribution state of storage cells in a semiconductor memory.

### BACKGROUND ART

A semiconductor memory tester analyzes defects in each storage cell in a semiconductor memory (hereinafter simply referred to as a “memory”) by reading or writing data from or to the storage cell. In general, the semiconductor memory tester is composed of a timing generator 110, a pattern generator 112, waveform shaper 114, a logic comparator 116, and a fail memory 118 as shown in FIG. 7. An address and data generated by the pattern generator 112 have their waveforms shaped by the waveform shaper 114. The resultant data is input to a memory under test (MUT). The logic comparator 116 then compares the data read from the MUT with an expected value output by the pattern generator 112, to determine whether or not this storage cell is accepted. On the basis of a fail signal output by the logic comparator 116 and an address signal output by the pattern generator 112, the fail memory 118 stores fail information for each address. These series of operations are all performed synchronously with a system clock input to each section by the timing generator 110.

In this manner, the fail memory 118, included in the semiconductor memory tester, stores data on whether or not each storage cell of the MUT is acceptable. A host apparatus such as an external workstation collects this data to check its contents, thus executing various types of defect analyses on this memory.

For example, the host apparatus can display the fail distribution state of a mass DRAM using a predetermined memory device evaluation tool. Further, by designating a print command provided in the memory device evaluation tool, the displayed fail distribution state can be printed on a predetermined sheet with the screen image maintained.

In the conventional defect analysis carried out by the host apparatus, if the fail distribution state is printed, the contents displayed on the screen are output as they are. Since a display such as a CRT (Cathode Ray Tube) or an LCD (Liquid Crystal Display) has a low resolution, a possible display range on one screen is narrow. Thus, when the fail distribution state of the entire memory is printed, a large number of display and printing operations must be performed. Consequently, a large amount of time and labor is required to output analysis results. For example, if the maximum size of fail information that can be displayed on one screen is 256 Kbit (512×512), when all fail information in a 64-Mbit DRAM is to be displayed, display contents must be switched 256 times. This requires an enormous amount of labor. Further, to print all fail information from the 64-Mbit DRAM on one sheet, the displayed contents must be printed upon each of the 256 display switching operations, with the resultant 256 print sheets stuck together for edition. Further, adjacent sheets must be aligned with each other. This requires a larger amount of time and labor than the above described display operation. Since a large amount of time and labor is thus required to print and edit the results of fail analysis, it has been desirable to develop a method of reducing this amount.

### DISCLOSURE OF THE INVENTION

The present invention has been achieved in view of this point. It is an object of the present invention to provide a fail analyzer that can reduce the amount of time and labor required to print and edit the results of fail analysis. It is another object of the present invention to provide a fail analyzer that can execute other processes on the basis of the results of failure analysis.

To attain these objects, the present invention provides a fail analyzer. To use a printer to print contents of fail bit map data on a semiconductor memory which has been obtained by tests executed by a semiconductor memory tester, the fail analyzer of the present invention comprises first storage unit for storing fail bit map data, and print data generating unit for reading the fail bit map data and for generating print data taking into account a printing resolution of the printer. The results of fail analysis are printed on the basis of the resolution of the printer, which is generally higher than that of a screen display. Accordingly, it is possible to increase the range of the results of fail analysis contained within one sheet, compared to the case in which the results of fail analysis are printed on the basis of the display resolution as with the prior art. This reduces the number of repeated printing operations required to print the results of fail analysis corresponding to the entire semiconductor memory or its partial area. This in turn reduces the amount of labor required for printing. Further, the number of sheets printed is reduced to decrease the amount of labor required to stick print sheets together to edit the results of fail analysis.

Further, in generating print data corresponding to a plurality of print sheets, the print data generating unit desirably generates print data so as to contain predetermined markers indicative of corresponding positions of two adjacent print sheets so that addresses of the semiconductor memory constitute consecutive numbers. Thus, if the results of fail analysis of the semiconductor memory are printed on two or more print sheets by being divided into the same number of pieces, these print sheets can be aligned with one another by adjusting the positions of the markers, contained in the print sheets, so that the markers of adjacent print sheets are superimposed on each other. Thus, it is possible to further reduce the amount of labor required for the editing operation of sticking together the results of fail analysis printed on a plurality of sheets by being divided into the same number of pieces.

Further, desirably, the fail bit map data includes logical fail bit map data indicating a relationship between logical addresses of the semiconductor memory and corresponding fail information and physical fail bit map data indicating a relationship between physical addresses of the semiconductor memory and corresponding fail information, and physical converting unit reads the logical fail bit map data from the first storage unit to convert the data into physical fail bit map data. The physical converting unit enables both or arbitrarily selected one of the logical fail bit map data and physical fail bit map data to be printed as required taking the resolution of the printer into account.

Further, desirably, print item setting unit is provided to allow a user to set detail items for generation of print data by the print data generating unit using a user graphical interface screen. Thus, the user can give an instruction to set the detail items such as the resolution of the printer while viewing the user graphical interface (GUI) screen. This allows the user to operate the analyzer more easily and reduces the time required for operations.

Furthermore, desirably, the print data generating unit outputs print data in the form of a file of a general purpose data format and stores the print data output in the form of a file, in second storage unit. Since the results of fail analysis are output in the form of the file of the general purpose data format, it is possible to read this file and execute secondary processing on the results of fail analysis.

Moreover, the general purpose data format is desirably PostScript. PostScript is a page description language (PDL) used to describe text or image pages output to the printer or the display. It can be widely used because of its independence of output devices. This makes it particularly easy to execute processing or the like on the results of fail analysis having this format.

### BRIEF DESCRIPTION OF THE DRAWINGS

FIG. 1 is a diagram showing a configuration of a fail analyzer of one embodiment;

FIG. 2 is a diagram showing a layout of a GUI screen displayed on a display by a print item setting section;

FIG. 3 is a diagram illustrating a print layout;

FIG. 4 is a diagram illustrating a print layout;

FIG. 5 is a flow chart showing an operational procedure when the fail analyzer of the present embodiment is used to print a fail distribution or output data in file form;

FIG. 6 is a diagram showing an example of the results of printing of a fail distribution; and

FIG. 7 is a schematic diagram showing a configuration of a conventional semiconductor memory tester.

### BEST MODE FOR CARRYING OUT THE INVENTION

With reference to the drawings, description will be given of a fail analyzer of one embodiment to which the present invention has been applied.

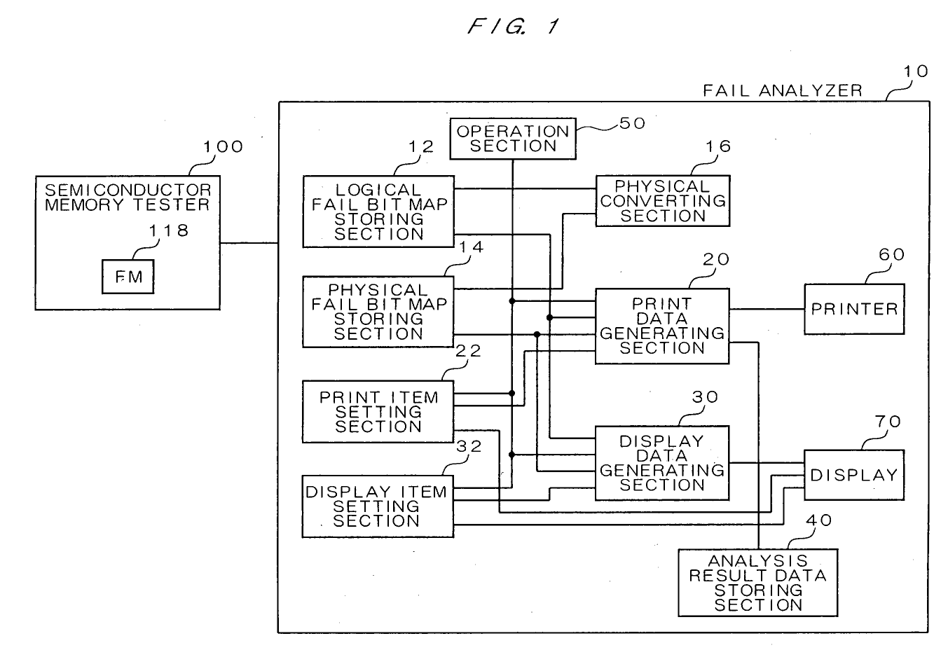

FIG. 1 is a diagram showing a configuration of the fail analyzer of the present embodiment. The fail analyzer 10 shown in FIG. 1 is comprising a logical fail bit map storing section 12, a physical fail bit map storing section 14, a physical converting section 16, a print data generating section 20, a print item setting section 22, a display data generating section 30, a display item setting section 32, an analysis result data storing section 40, an operation section 50, a printer 60, and a display 70. The fail analyzer 10 can be constructed using a general purpose computer such as a workstation, for example.

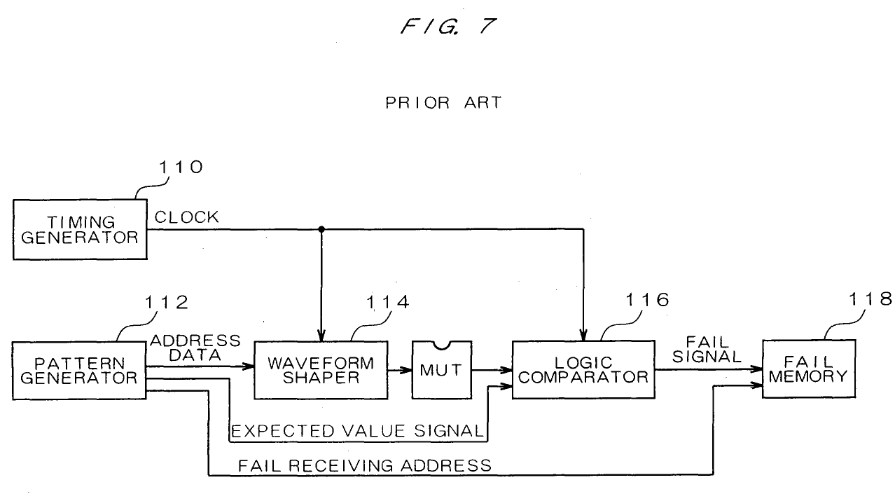

The fail analyzer 10, shown in FIG. 1, is connected to a semiconductor memory tester 100 to read fail information stored in a fail memory (FM) 118 to carry out various fail analyses to determine, for example, a fail distribution state. Further, the semiconductor memory tester 100 tests the acceptability of a memory (not shown) and has the configuration shown in FIG. 7.

The logical fail bit map storing section 12 stores logical fail bit map data corresponding to the memory under test. Further, the physical fail bit map storing section 14 stores physical fail bit map data corresponding to the memory under test. The physical converting section 16 reads the logical fail bit map data stored in the logical fail bit map storing section 12 to convert the data into physical fail bit map data. The physical fail bit map data obtained by this conversion is stored in the physical fail bit map storing section 14.

The actual physical arrangement of storage cells in the memory differs from that in address information (logical addresses) input to the memory. Thus, even with read fail information, which has been stored in the fail memory 118 in the semiconductor memory tester 100, a user may not determine which storage cells are defective. A “fail bit map” shows addresses of the memory at which defects have been detected. The fail bit map is classified into a logical fail bit map and a physical fail bit map. The logical fail bit map is three-dimensional and uses logical addresses X and Y and I/O numbers, or may be four-dimensional if logical addresses Z are added. The logical fail bit map is obtained on the basis of the fail information read from the fail memory 118 in the semiconductor memory tester 100. The physical fail bit map is two-dimensional and uses physical addresses X and Y as coordinates. It is used, for example, to check the physical arrangement of defective storage cells in the semiconductor memory.

In general, “physical conversion” is a conversion of a logical fail bit map into a physical fail bit map. The physical converting section 16 carries out this physical conversion.

The print data generating section 20 generates print data of a PostScript format, the data being required to print, using the printer 60, a fail distribution shown using logical or physical fail bit map data. According to an operational instruction from the user, the print item setting section 22 sets detail items required to generate print data using the print data generating section 20 by executing a GUI (Graphical User Interface) process. Specific examples of detail items will be described later.

The display data generating section 30 generates display data required to display a fail distribution shown in the form of a logical or physical fail bit map, using the display 70. The display item setting section 32 sets detail items required to generate display data using the display data generating section 30.

The analysis result data storing section 40 stores print data of the PostScript format output by the print data generating section 20, as saved or processing data. PostScript is a page description language (PDL) developed by Adobe Systems, U.S. and is used to describe text and image pages output to the printer or display. PostScript currently has levels 1 to 3, and any of these levels may be used. However, it is desirable to use the level 1, which can be most widely used.

The operation section 50 is used by the user to input various instructions, and includes a mouse as a pointing device which specifies an arbitrary position on a display screen of the display 70 and a keyboard that allows the user to input numerals, alphabets, or various symbols using ten keys, alphabet keys, and the like.

The logical fail bit map storing section 12 and the physical fail bit map storing section 14 correspond to first storage unit. The analysis result data storing section 40 corresponds to second storage unit. The print data generating section 20 corresponds to print data generating unit. The physical converting section 16 corresponds to physical converting unit. The print item setting unit 22 corresponds to print item setting unit.

The fail analyzer 10 of the present embodiment is configured as described above. Its operations will be described below. For example, it is assumed that the fail information stored in the fail memory 118 in the semiconductor memory tester 100 has been read by the fail analyzer 10 and stored in the logical fail bit map storing section 12. Further, it is assumed that the physical converting section 16 has used the data stored in the logical fail bit map storing section 12 to carry out a physical conversion and stored the resulting physical fail bit map data in the physical fail bit map storing section 14.

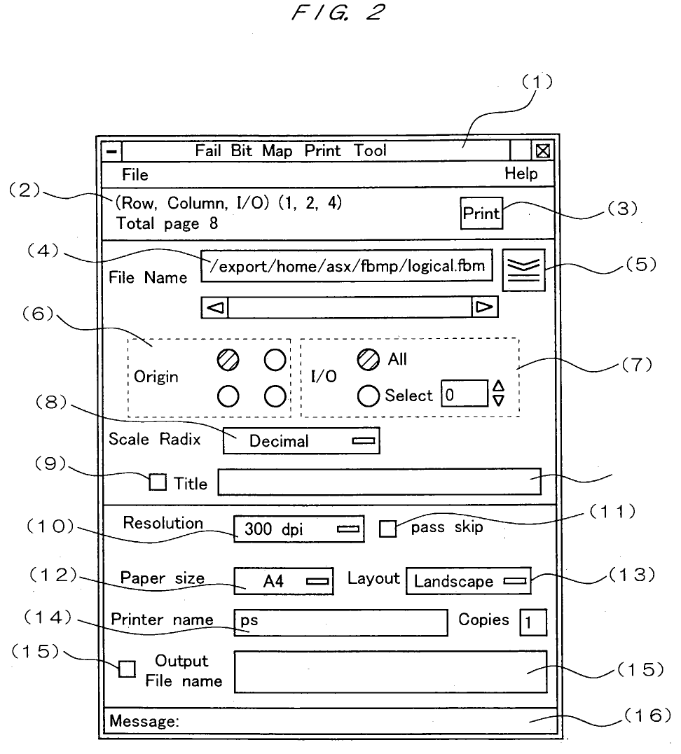

FIG. 2 shows a layout of a GUI screen displayed on the display 70 by the print item setting section 22. Elements constituting the GUI screen shown in FIG. 2 will be sequentially described below.

(1) Menu Bar

The screen contains a “File” menu and a “Help” menu, which are selectable. By clicking the “File” menu using the mouse, provided in the operation section 50, the corresponding pulldown menu can be displayed. For example, this pulldown menu contains an “Open” command specified to open a file open window, a “Print” command used to give an instruction to print a fail distribution corresponding to a fail bit map, and an “Exit” command specified to give an instruction to end a process of printing fail information using this GUI screen.

(2) Page Information

“Page number” region displays the total number of pages available if fail information is printed which corresponds to the semiconductor memory to be analyzed, and also displays additional information. For example, for a physical fail bit map, this region displays a combination of a row and a column, and a total page. On the other hand, for a logical fail bit map, this region displays a combination of a row, a column, and an I/O number, and a total page. The row indicates the number of pages in a vertical direction (Y direction), whereas the column indicates the number of pages in a horizontal direction (X direction).

(3) “Print” Button

This button is used to give an instruction to print a fail distribution corresponding to a fail bit map. The user can give an instruction for printing by clicking this button instead of specifying the “Print” command, contained in the “File” menu, described above.

(4) “File Name” Text Box

This text box is used to specify a file name of fail data whose printing is desired.

(5) “File Open” Button

This button is used to open the file open window.

(6) “Origin” Button

This button is used to specify the origin of fail data. It includes two buttons lengthwise and two buttons breadth wise, i.e. a total of four buttons. By selecting any of these buttons, the user can specify the origin position corresponding to the selected button. For example, if the user desires to designate an upper left position as the origin, he or she can select the button arranged in the upper left of this region. If the user desires to designate a lower right position as the origin, he or she can select the button arranged in the lower right of this region.

(7) “I/O Select” Button

This button is used to specify I/Os for a logical fail bit map. If the user desires to set all I/Os for printing, he or she can select an “All” button. Alternatively, if the user desires to set any of the I/Os for printing, he or she specifies a “Select” button and inputs the corresponding I/O number to a text box provided at the right of this button.

(8) “Scale Radix” Menu

This menu is used to set a scale radix. A decimal or hexadecimal number can be set as a scale radix. To set a decimal number as a scale radix, the user selects “Decimal”. To set a hexadecimal number as a scale radix, the user selects “hexadecimal”.

(9) “Title” Button and “Title” Text Box

To set a title, the user must turn the “Title” button on and input the title in an adjacent text box. If the “Title” button is turned off, the title input to the text box will not be printed.

(10) “Resolution” Menu

To set a resolution, the user selects one of a plurality of selection candidates contained in a “Resolution” menu. For example, the user selects one of five resolutions 1,200, 600, 300, 150, and 75 dpi, which equals the resolution of the printer 60.

(11) “Pass Skip” Button

This button is used to specify a pass skip mode. Turning this button on avoids printing operation those areas which contain no fail data.

(12) “Paper Size” Menu

This menu is used to set the size of paper used for printing. For example, a selectable print size can be selected from a list of A4, A3, . . . , or the like.

(13) “Layout” Menu

This menu is used to set a print layout. The user can specify Landscape or Portrait as a print layout.

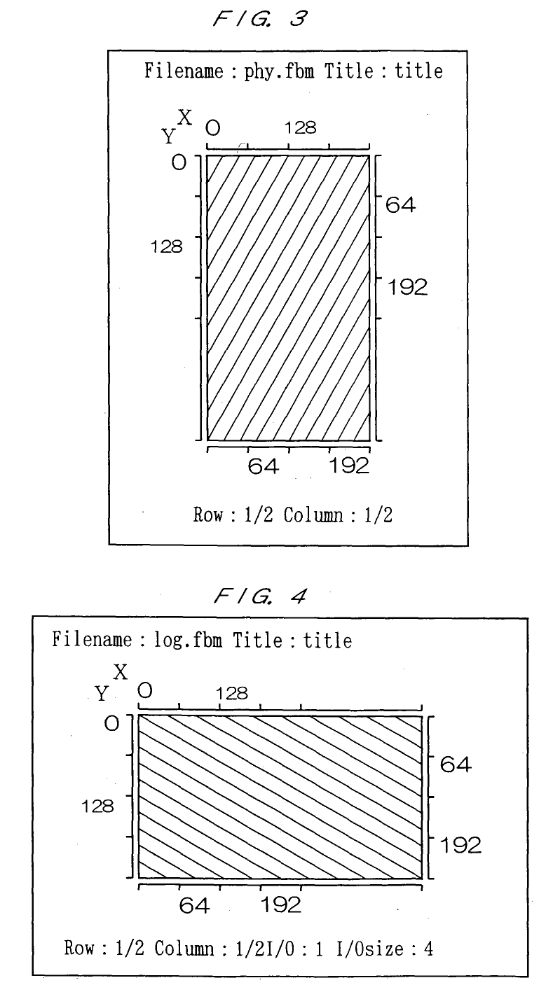

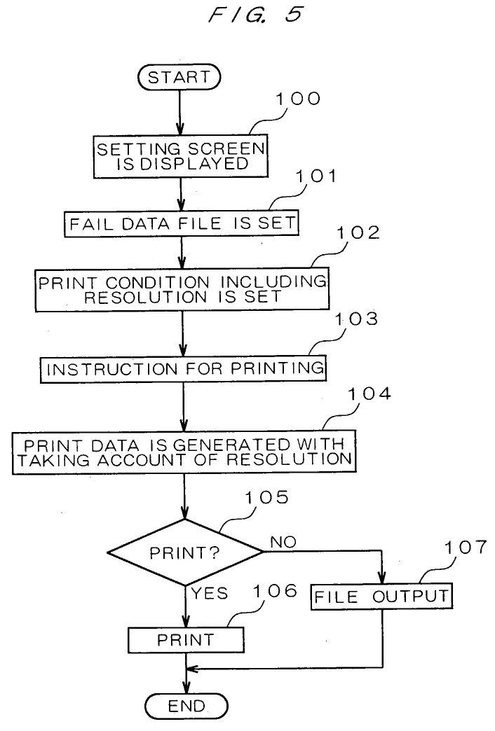

FIGS. 3 and 4 illustrate print layouts. As shown in FIG. 3, if file data is printed in the vertical direction, Portrait is specified as a print layout. As shown in FIG. 4, if the file data is printed in the horizontal direction, Landscape is specified as a print layout.

(14) “Printer Name” Text Box

This text box is used to specify the name of the printer 60 that prints a fail distribution. If this text box is blank, the default printer 60 is specified.

(15) “Output File Name” Button and “Output File Name” Text Box

This button is used to switch an output destination from the printer 60 to a file. In this case, PostScript is specified as a file data format. Further, the user uses the “Output File Name” text box, located adjacent to this button, to input the name of a destination file.

(16) “Message” Area

This area is used to display a predetermined message indicating the results of printing by the printer 60 or the results of a file output. For example, if a printing operation performed by the printer 60 is completed normally, “Process is completed” is shown in this area.

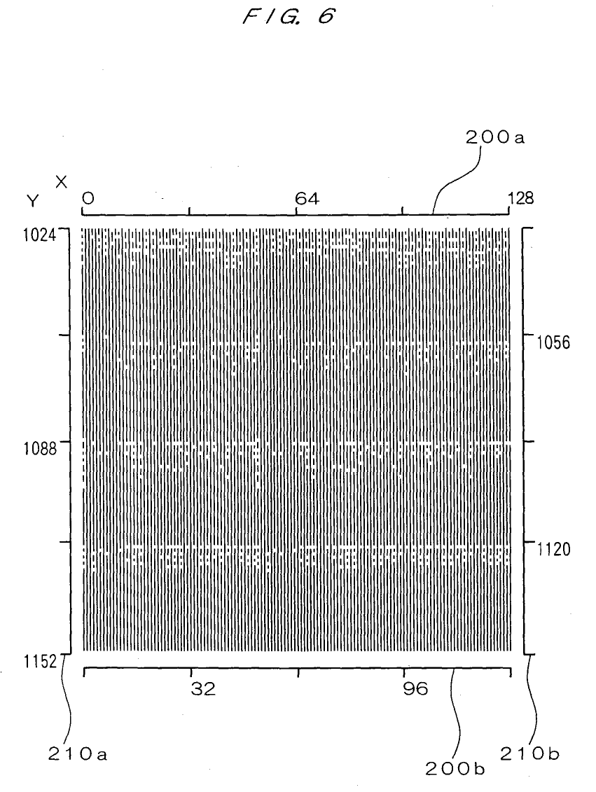

FIG. 5 is a flow chart showing an operational procedure used to print a fail distribution or output it to a file using the fail analyzer of the present embodiment.

When the user operates the operation section 50 to run a fail bit map print tool, the print item setting section 22 first displays the detail item setting screen shown in FIG. 2 in order to set various items required for printing (step 100). The user then sets a fail data file (step 101) and sets print conditions including the resolution of the printer 60 (step 102). The user sets the fail data file by using the keyboard or the like, provided in the operation section 50, to use the file name input to the “File Name” text box (4) in the setting screen shown in FIG. 2. Similarly, the user sets the print conditions including the resolution by using the mouse or keyboard, provided in the operation section 50, to operate various menus and buttons such as the “Resolution” menu in the setting screen shown in FIG. 2.

After setting various items, the user clicks the “Print” button in an operation screen to given an instruction for printing (step 103). Then, the print data generating section 20 generates print data (step 104). The print data is generated on the basis of the various contents set at step S102, by reading data to be printed from the logical fail bit map storing section 12 or the physical fail bit map storing section 14 on the basis of the file name set at step 101. Further, the print data is generated in the PostScript format of the level 1.

Then, the print data generating section 20 determines whether or not a printing operation is to be performed using the generated print data (step 105). This determination is made by checking whether or not the “Output File Name” button (15) in the setting screen shown in FIG. 2 has been turned on.

If this button has been turned off, the print data generating section 20 sends an instruction to start a printing operation, to the printer 60 together with the generated print data. The printer 60 then executes a print process (step 106). On the other hand, if the above button has been turned on, the print data generating section 20 determines that the instruction is for a file output (the result of the determination at step 105 is negative). The print data generating section 20 then sends an instruction to store the corresponding file, to the analysis result data storing section 40 together with the print data generated. Thus, the analysis result data storing section 40 stores this file (step 107).

FIG. 6 shows an example of the results of printing of a fail distribution. This Figure shows a fail distribution in a physical fail bit map by way of example. For example, X addresses correspond to a range from 0 to 127, whereas Y addresses correspond to a range from 1,024 to 1,151. If the resolution of the printer 60 is set at 600 dpi or the like, the ranges of X and Y addresses contained in an A4-sized print sheet are wider. However, FIG. 6 shows a case with a very low resolution for explanation. As shown in FIG. 6, markers 200a and 200b also used as scales for the X addresses are provided above and below a region indicating a fail distribution. Markers 210a and 210b also used as scales for the Y addresses are provided at the right and left of this region. These markers allow the easy alignment of fail distributions in which X or Y addresses constitute consecutive numbers. This reduces the amount of labor and time required to stick sheets together. For example, auxiliary lines are drawn on a printed sheet so as to join the upper ends of the markers 210a and 210b together, which extend in the Y direction, and the printed sheet is cut along these lines using a pair of scissors or the like. Then, a piece of sheet can be formed in which the upper end of the fail distribution constitutes an edge. Consequently, this fail distribution can be stuck to another similar fail distribution so as to lie precisely adjacent to it in such a manner that the Y addresses in these fail distributions constitute consecutive numbers.

In this manner, the fail analyzer 10 of the present embodiment prints the results of fail analysis (fail distributions) on the basis of the resolution of the printer 60. Accordingly, compared to the case in which the results of fail analysis are printed on the basis of the display resolution as with the prior art, the range of the results of fail analysis contained within one sheet can be widened. This reduces the number of repeated printing operations required to print the results of fail analysis corresponding to the entire semiconductor memory or its partial area. This in turn reduces the amount of labor required for printing. Further, the number of sheets printed is reduced to decrease the amount of labor required to stick printed sheets together to edit the results of fail analysis. In particular, the alignment markers 200a, 200b, 210a, and 210b are provided together with the results of fail analysis. Accordingly, if the results of fail analysis are printed on two or more print sheets by being divided into the same number of pieces, the fail analysis distributions on the adjacent print sheets can be aligned with one another using these markers. Thus, it is possible to further reduce the amount of labor required for the editing operation of sticking together the results of fail analysis printed on a plurality of sheets by being divided into the same number of pieces.

Further, the fail analyzer 10 of the present embodiment is provided with the physical converting section 16. The physical converting section enables both or arbitrarily selected one of the logical fail bit map data and physical fail bit map data to be printed as required taking the resolution of the printer 60 into account.

Furthermore, the user can set the detail items such as the resolution of the printer 60 while viewing the GUI screen. This allows the user to operate the analyzer more easily and reduces the time required for operations. Moreover, the results of fail analysis can be output in the data form of a file of the Postscript format, which is widely used. Consequently, it is possible to read this file and execute secondary processing on the results of fail analysis.

### Industrial Applicability

As described above, according to the present invention, it is possible to reduce the number of repeated printing operations required to print the results of fail analysis corresponding to the entire semiconductor memory or its partial area. Further, the number of sheets printed is reduced to decrease the amount of labor required to stick print sheets together to edit the results of fail analysis.

1. A fail analyzer that uses a printer to print contents of fail bit map data on a semiconductor memory which has been obtained by tests executed by a semiconductor memory tester, characterized by comprising:
first storage unit for storing fail bit map data; and
print data generating unit for reading said fail bit map data stored in said first storage unit to generate print data taking into account a print resolution of said printer and outputting the print data to said printer.

2. The fail analyzer according to claim 1, characterized in that in generating said print data corresponding to said plurality of print sheets corresponding to the whole or part of said semiconductor memory, said print data generating unit generates said print data so as to contain predetermined markers indicative of corresponding positions of adjacent two of said print sheets so that addresses of said semiconductor memory constitute consecutive numbers.

3. The fail analyzer according to claim 1, characterized in that said fail bit map data includes logical fail bit map data indicating a relationship between logical addresses of said semiconductor memory and corresponding fail information and physical fail bit map data indicating a relationship between physical addresses of said semiconductor memory and corresponding fail information, and
said physical analyzer further comprises physical converting unit for reading the logical fail bit map data to convert the data into physical fail bit map data.

4. The fail analyzer according to claim 1, characterized by further comprising print item setting unit for allowing a user to set detail items for generation of print data by said print data generating unit using a user graphical interface screen.

5. The fail analyzer according to claim 1, characterized in that said print data generating unit outputs said print data in the form of a file of a general purpose data format, and
said fail analyzer further comprises second storage unit for storing said print data output in the form of a file.

6. The fail analyzer according to claim 5, characterized in that said general purpose data format is PostScript.
